(19) United States
(12) Patent Application Publication
(10) Pub. No.: US 2013/0149941 A1
(43) Pub. Date: Jun. 13, 2013

(54) Method Of Machining Semiconductor Substrate And Apparatus For Machining Semiconductor Substrate

(71) Applicant: Samsung Corning Precision Materials Co., Ltd., Gyeongsangbuk-do (KR)

(72) Inventors: Sungwoo Eo, ChungCheongNam-Do (KR); KyoungJun Kim, ChungCheongNam-Do (KR)

(73) Assignee: SAMSUNG CORNING PRECISION MATERIALS CO., LTD., Gyeongsangbuk-do (KR)

(21) Appl. No.: 13/712,017

(22) Filed: Dec. 12, 2012

(30) Foreign Application Priority Data
Dec. 13, 2011 (KR) 10-2011-0133632

(51) Int. Cl. H01L 21/463

(52) U.S. Cl. CPC H01L 21/463
USPC 451/36; 451/317

(57) ABSTRACT

A method of machining a semiconductor substrate using a soft polishing pad and an apparatus for machining a semiconductor substrate which has a soft polishing pad. The method includes the steps of lapping a surface of the semiconductor substrate, and polishing the lapped surface of the semiconductor substrate. The step of polishing the lapped surface of the semiconductor substrate includes polishing the lapped surface of the semiconductor substrate using slurry containing an abrasive interposed between the semiconductor substrate and a polishing pad which has a shore D hardness of 65 or less.

### CROSS REFERENCE TO RELATED APPLICATION

The present application claims priority from Korean Patent Application Number 10-2011-0133632 filed on Dec. 13, 2011, the entire contents of which application are incorporated herein for all purposes by this reference.

### BACKGROUND OF THE INVENTION

1. Field of the Invention

The present invention relates to a method of machining a semiconductor substrate and an apparatus for machining a semiconductor substrate, and more particularly, to a method of machining a semiconductor substrate using a soft polishing pad and an apparatus for machining a semiconductor substrate which has a soft polishing pad.

2. Description of Related Art

A substrate, such as a silicon (Si) wafer, a sapphire substrate, a gallium nitride (GaN) substrate, or the like, which is used for the fabrication of semiconductor devices is manufactured by a surface machining process including lapping and polishing which is intended to flatten the substrate.

More specifically, a Si wafer is manufactured by slicing a rod-shaped single crystal ingot into several sheets of wafers, followed by the surface machining, such as lapping and polishing.

In addition, a GaN substrate which has ideal characteristics for optical devices and high-temperature and high-power devices, attributable to its wide direct transition energy band gap as well as great interatomic bonding force and high thermal conductivity, is manufactured using a GaN film which is grown on a heterogeneous substrate. The GaN film grown on the heterogeneous substrate is vulnerable to warping while being grown or after having been grown, attributable to the differences in coefficients of thermal expansion and lattice constants between the GaN film and the heterogeneous substrate. The warped GaN film is flattened due to the surface machining, such as lapping and polishing, so as to form a GaN substrate.

In detail, a method of machining the surface of a semiconductor substrate of the related art includes, first, lapping the semiconductor substrate. Although the lapping imparts the semiconductor substrate with a predetermined thickness and a predetermined degree of flatness, the surface of the semiconductor substrate is damaged due to the lapping, thereby producing a subsurface damage layer.

Afterwards, the lapped surface of the semiconductor substrate is polished using a polishing pad made of tin or tin resin together with a diamond slurry having a grain diameter of 100 nm or less. The polishing forms a mirror surface having a surface roughness Ra in the range from 2 Å to 4 Å, and removes the subsurface damage layer which is formed due to the lapping. Although the polishing imparts the semiconductor substrate with a surface quality which is equal or comparable to that of a mirror surface, mechanical energy and impact energy that is caused due to the polishing using the hard polishing pad made of tin or tin resin is directly transferred to the semiconductor substrate, thereby forming the subsurface damage layer in the semiconductor substrate.

FIG. 1 is a picture depicting the surface roughness of a GaN substrate which is machined by a method of the related art, and FIG. 2 is a picture depicting a subsurface damage layer which is present in the GaN substrate shown in FIG. 1. FIG. 1 is the picture taken by Zygo, a surface roughness tester, and FIG. 2 is a picture of the subsurface damage layer that is measured using photoluminescence. As shown in FIG. 1 and FIG. 2, it can be appreciated that, although the machined GaN substrate has the mirror surface which has an average roughness Ra of 0.204 nm, it also has the subsurface damage layer.

Finally, the subsurface damage layer which is produced due to the polishing is removed by a dry etching process such as inductive coupled plasma reactive ion etching (ICP-RIE).

However, when the subsurface damage layer is removed due to the dry etching, scratches which were not observed during the polishing are formed in the surface of the semiconductor substrate. When the subsurface damage layer is selectively etched, linear scratches are exposed on the surface.

FIG. 3 is a picture depicting the surface roughness of a GaN substrate which is machined by another related art method, and FIG. 4 is a picture depicting a subsurface damage layer which is present in the GaN substrate shown in FIG. 3. As in the former method, the surface roughness is measured using Zygo, and the subsurface damage layer is measured using photoluminescence. Referring to FIG. 3 and FIG. 4, it can be appreciated that, although the subsurface damage layer is removed from the GaN substrate due to the dry etching, scratches are exposed on the surface of the GaN substrate.

Such scratches increase the surface roughness of the semiconductor substrate. When semiconductor devices are manufactured using such semiconductor substrates, a low-quality epitaxial layer is deposited during epitaxy which is intended for the manufacture of semiconductor devices, thereby degrading the performance of resultant semiconductor devices, which is problematic.

The information disclosed in the Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a method of machining a semiconductor substrate and an apparatus for machining a semiconductor substrate which prevent a subsurface damage layer.

In an aspect of the present invention, provided is a method of machining a semiconductor substrate. The method includes the following steps of: lapping a surface of the semiconductor substrate; and polishing the lapped surface of the semiconductor substrate. The step of polishing the lapped surface of the semiconductor substrate includes polishing the lapped surface of the semiconductor substrate using slurry containing an abrasive interposed between the semiconductor substrate and a polishing pad which has a shore D hardness of 65 or less.

In an exemplary embodiment, the polishing pad may be made of polyurethane.

In an exemplary embodiment, the abrasive may be implemented as a diamond having an average diameter D50 of 100 nm or less.

In an exemplary embodiment, the step of polishing the lapped surface of the semiconductor substrate may include polishing the lapped surface of the semiconductor substrate such that the semiconductor has a surface roughness ranging from 2 Å to 4 Å.

In an exemplary embodiment, the method may further include the step of cleaning the semiconductor substrate by removing impurities from the semiconductor substrate which has been polished and drying the semiconductor substrate.

In an exemplary embodiment, the semiconductor substrate may be implemented as a gallium nitride (GaN) substrate or a silicon carbide (SiC) substrate.

In another aspect of the present invention, provided is an apparatus for machining a semiconductor substrate. The apparatus includes a surface plate provided with a polishing pad having a shore D hardness of 65 or less; a slurry supplying unit which supplies polishing slurry containing an abrasive onto a surface of the polishing pad; and a substrate plate configured to face the surface plate. The surface plate rotates on the axis thereof while holding the semiconductor substrate, and presses the semiconductor substrate against the polishing pad while allowing the semiconductor substrate to slide on the polishing pad.

In an exemplary embodiment, the polishing pad may be made of polyurethane.

In an exemplary embodiment, the substrate plate may hold a plurality of the semiconductor substrates.

According to embodiments of the invention, it is possible to manufacture a semiconductor substrate without a subsurface damage layer by absorbing mechanical energy and impact energy which occur during the processing of the semiconductor substrate.

In addition, it is possible to manufacture a semiconductor substrate having an excellent surface roughness.

Furthermore, it is possible to obtain semiconductor substrates with improved productivity by simplifying the process of machining the semiconductor substrate.

The methods and apparatuses of the present invention have other features and advantages which will be apparent from, or are set forth in greater detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a picture depicting the surface roughness of a GaN substrate which is machined by a related art method;

FIG. 2 is a picture depicting a subsurface damage layer which is present in the GaN substrate shown in FIG. 1;

FIG. 3 is a picture depicting the surface roughness of a GaN substrate which is machined by another related art method;

FIG. 4 is a picture depicting a subsurface damage layer which is present in the GaN substrate shown in FIG. 3;

FIG. 5 is a schematic flowchart depicting a method of machining a semiconductor substrate according to an embodiment of the invention;

FIG. 6 and FIG. 7 are pictures depicting the surface roughness of a GaN substrate which was machined according to an example of the invention;

FIG. 8 is a picture depicting a subsurface damage layer of the GaN substrate shown in FIG. 6 and FIG. 7; and

FIG. 9 is a schematic configuration view of an apparatus for machining a semiconductor substrate according to another embodiment of the invention.

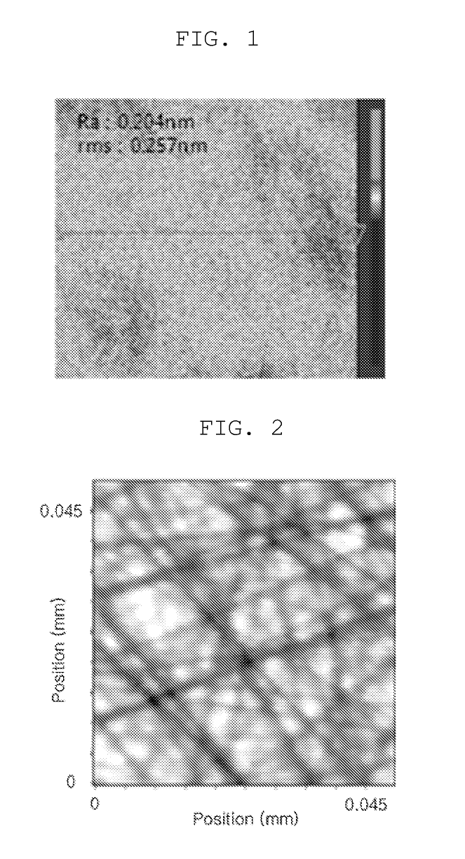

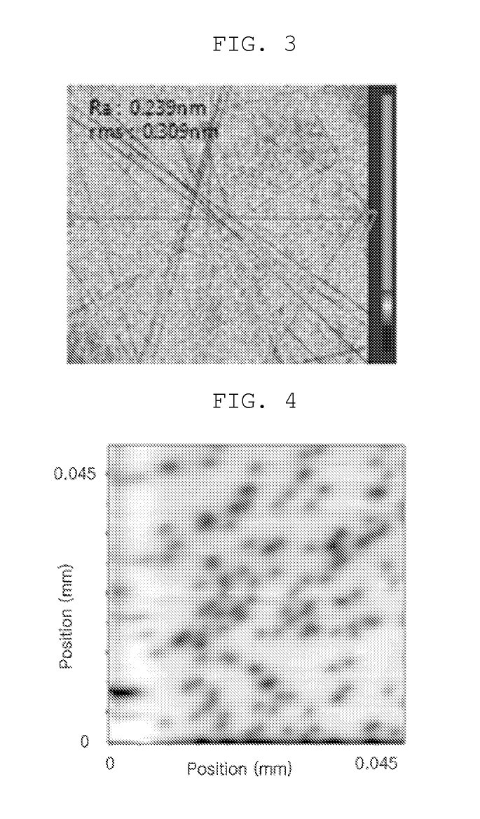

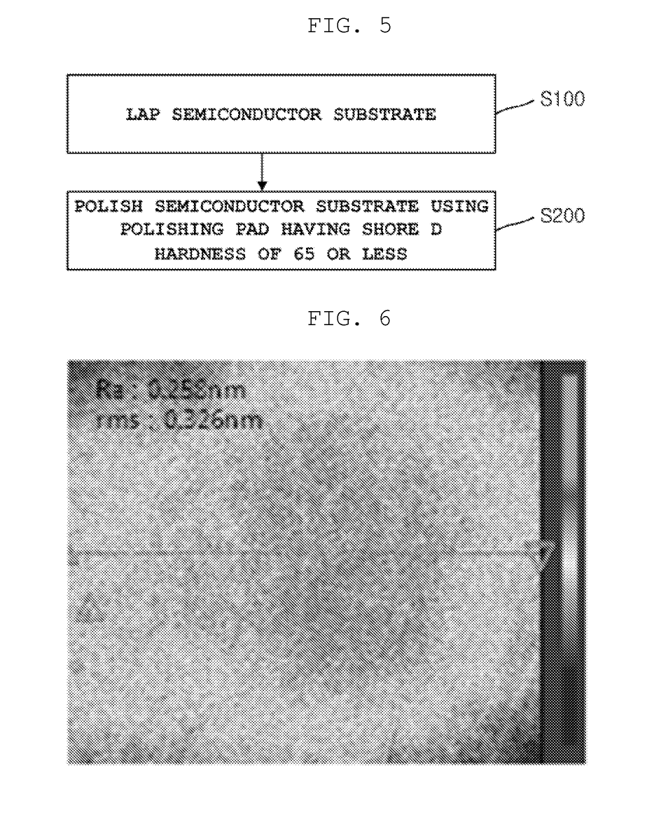

### DETAILED DESCRIPTION OF THE INVENTION

Reference will now be made in detail to a method of machining a semiconductor substrate and an apparatus for machining a semiconductor substrate according to the present invention, embodiments of which are illustrated in the accompanying drawings and described below, so that a person having ordinary skill in the art to which the present invention relates can easily put the present invention into practice.

Throughout this document, reference should be made to the drawings, in which the same reference numerals and signs are used throughout the different drawings to designate the same or similar components. In the following description of the present invention, detailed descriptions of known functions and components incorporated herein will be omitted when they may make the subject matter of the present invention unclear.

FIG. 5 is a schematic flowchart depicting a method of machining a semiconductor substrate according to an embodiment of the invention.

Referring to FIG. 5, the method of machining a semiconductor substrate of this embodiment includes a lapping step and a polishing step.

In order to machine the semiconductor substrate, first, at S100, the lapping step of grinding and flattening the semiconductor substrate to a predetermined thickness is carried out.

The semiconductor substrate may be implemented as a variety of substrates which is to be used as a substrate for semiconductor devices, such as a gallium nitride (GaN) substrate or a silicon carbide (SiC) substrate.

The lapping step is carried out by uniformly grinding the semiconductor substrate at a fast speed using an abrasive and slurry containing a dispersant. The abrasive has a large particle diameter, preferably, in the range from 6 μm to 9 μm. The dispersant in the slurry contains a thickening component, a dispersing component, a stain-proofing component, a lubricating component and the like.

When the semiconductor substrate is lapped, a subsurface damage layer is formed in the semiconductor substrate, as described above.

Afterwards, at S200, the step of polishing the lapped surface of the semiconductor substrate is carried out in order to remove the subsurface damage layer that is formed by the lapping and converting the lapped surface of the semiconductor substrate into a mirror surface.

The polishing can be carried out until the semiconductor substrate has a surface roughness ranging from 2 Å to 4 Å.

The polishing is carried out using a polishing pad which has a shore D hardness of 65 or less and slurry which contains an abrasive.

The polishing pad having the shore D hardness of 65 or less can be made of soft polyurethane.

It is preferred that the abrasive be implemented as a diamond having an average diameter D50 of 100 nm or less.

As described above, since the lapped surface of the semiconductor substrate is polished using the soft polishing pad having the shore D hardness of 65 or less, a subsurface damage layer can be prevented from being formed in the semiconductor substrate during the polishing, and the semiconductor substrate can have excellent surface roughness.

Specifically, when a semiconductor substrate is polished using the hard polishing pad made of metal as described above, mechanical energy and impact energy that occurs during the processing is directly transferred to the semiconductor substrate, thereby producing the subsurface damage layer in the semiconductor substrate. In contrast, the present invention employs the soft polishing pad having the shore D hardness of 65 or less so that the soft polishing pad absorbs mechanical energy and impact energy that occurs during the step of polishing the semiconductor substrate. It is therefore possible to manufacture a semiconductor substrate which does not have a subsurface damage layer without having to undergo etching.

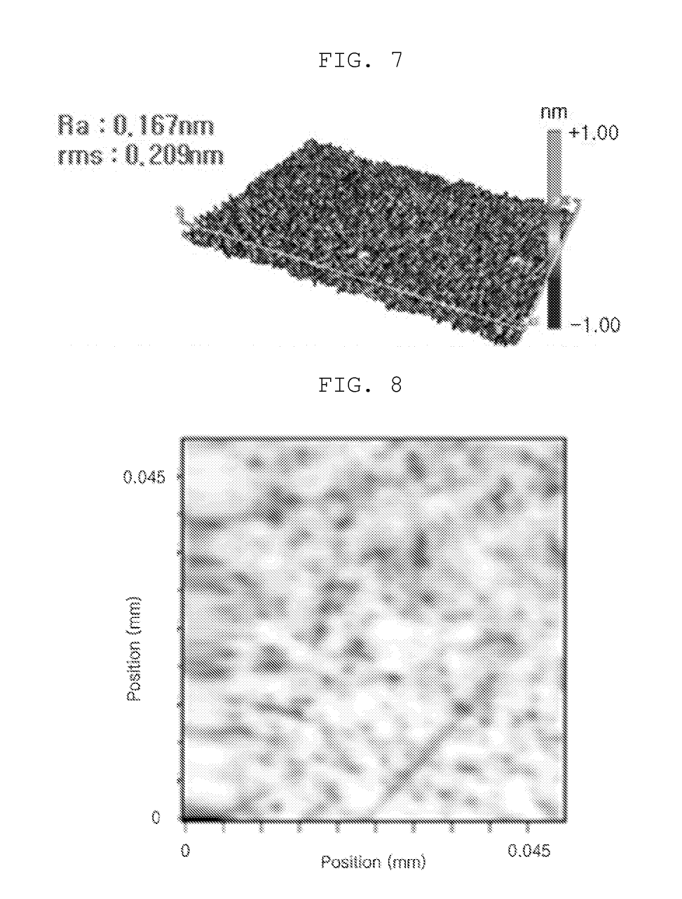

FIG. 6 and FIG. 7 are pictures depicting the surface roughness of a GaN substrate which was polished using a soft polishing pad and a diamond abrasive with a D50 of 100 nm or less according to an example of the invention, and FIG. 8 is a picture depicting a subsurface damage layer in the same GaN substrate. The surface roughness in FIG. 6 was measured using Zygo, and the subsurface damage layer shown in FIG. 8 was measured using photoluminescence.

As shown in FIG. 6 to FIG. 8, since the semiconductor substrate is machined according to the present invention, it is possible to manufacture the semiconductor substrate which has an excellent surface roughness without a subsurface damage layer.

The method of machining a semiconductor substrate of this embodiment may also include, after the polishing step, a cleaning step of removing impurities from the polished surface of the semiconductor substrate using a cleaning agent and then drying the cleaned surface of the semiconductor substrate.

Although it has been described in the Detailed Description of the Invention section that the polishing pad which has the shore D hardness of 65 or less is used only in the polishing step in consideration of the polishing speed of the semiconductor substrate, the polishing pad can be used earlier in the lapping step.

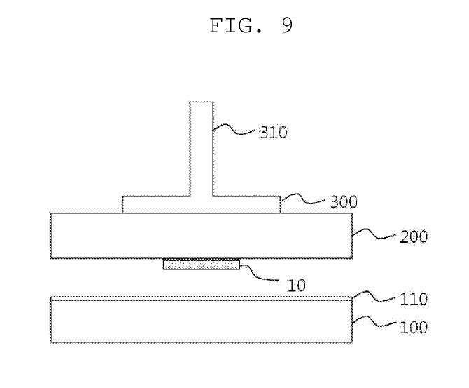

FIG. 9 is a schematic configuration view of an apparatus for machining a semiconductor substrate according to another embodiment of the invention.

Referring to FIG. 9, the apparatus for machining a semiconductor substrate of this embodiment includes a surface plate 100 which is provided with a polishing pad 110 on the upper surface thereof, the polishing pad having a shore D hardness of 65 or less. The apparatus also includes a slurry supplying unit (not shown) which supplies slurry containing an abrasive onto the surface of the polishing pad. The apparatus also includes a substrate plate 200 which faces the surface plate. The substrate plate 200 rotates on the axis thereof while holding a semiconductor substrate 10, and presses the semiconductor substrate 10 against the polishing pad 110 while allowing the semiconductor substrate 10 to slide on the polishing pad 110. A rotary holder 300 is provided above the surface plate 100, and is configured so as to be moved up and down and rotated by a shaft 310.

The semiconductor substrate 10 is attached to the substrate plate 200 via an adhering means such as wax.

Here, the polishing pad having the shore D hardness 65 or less can be made of a polyurethane material.

Since the semiconductor substrate is machined using the apparatus having the soft polishing pad, it is possible to protect the semiconductor substrate from mechanical energy and impact energy which occurs during a machining process, thereby preventing a subsurface damage layer from being formed in the semiconductor substrate.

In addition, the apparatus for machining a semiconductor substrate of this embodiment can simultaneously machine a plurality of semiconductor substrates by holding the plurality of semiconductor substrates by the substrate plate.

The foregoing descriptions of specific exemplary embodiments of the present invention have been presented with respect to the certain embodiments and drawings. They are not intended to be exhaustive or to limit the invention to the precise forms disclosed, and obviously many modifications and variations are possible for a person having ordinary skill in the art in light of the above teachings.

It is intended therefore that the scope of the invention not be limited to the foregoing embodiments, but be defined by the Claims appended hereto and their equivalents.

What is claimed is:

1. A method of machining a semiconductor substrate, comprising:
lapping a surface of the semiconductor substrate; and
polishing the lapped surface of the semiconductor substrate,
wherein polishing the lapped surface of the semiconductor substrate comprises polishing the lapped surface of the semiconductor substrate using slurry containing an abrasive interposed between the semiconductor substrate and a polishing pad which has a shore D hardness of 65 or less.

2. The method of claim 1, wherein the polishing pad comprises polyurethane.

3. The method of claim 1, wherein the abrasive comprises a diamond having an average diameter D50 of 100 nm or less.

4. The method of claim 1, wherein polishing the lapped surface of the semiconductor substrate comprises polishing the lapped surface of the semiconductor substrate such that the semiconductor has a surface roughness ranging from 2 Å to 4 Å.

5. The method of claim 1, further comprising cleaning the semiconductor substrate by removing impurities from the semiconductor substrate which has been polished and drying the semiconductor substrate.

6. The method of claim 1, wherein the semiconductor substrate comprises a gallium nitride (GaN) substrate or a silicon carbide (SiC) substrate.

7. An apparatus for machining a semiconductor substrate, comprising:
a surface plate provided with a polishing pad having a shore D hardness of 65 or less;
a slurry supplying unit for supplying a polishing slurry which contains an abrasive onto a surface of the polishing pad; and
a substrate plate configured to face the surface plate, the surface plate rotating on an axis thereof while holding the semiconductor substrate, and pressing the semiconductor substrate against the polishing pad while allowing the semiconductor substrate to slide on the polishing pad.

8. The apparatus of claim 7, wherein the polishing pad comprises polyurethane.

9. The apparatus of claim 7, wherein the substrate plate holds a plurality of the semiconductor substrates.
